(19) United States
(12) Patent Application Publication
(10) Pub. No.: US 2026/0238243 A1
(43) Pub. Date: Aug. 13, 2026

(54) RADIO FREQUENCY RECEIVER, MAGNETIC IMAGING SYSTEM AND METHOD

(71) Applicant: KONINKLIJKE PHILIPS N.V., EINDHOVEN (NL)

(72) Inventors: Christoph Günther Leussler, Hamburg (DE); Peter Vernickel, Hamburg (DE); Christian Findeklee, Norderstedt (DE)

(21) Appl. No.: 19/155,986

(22) PCT Filed: Feb. 6, 2024
(86) PCT No.: PCT/EP2024/052823

§ 371 Date: Aug. 13, 2025

(30) Foreign Application Priority Data
Feb. 20, 2023 (EP) 23157592.9

(51) Int. Cl. H04B 1/14; G01R 33/36

(52) U.S. Cl. CPC H04B 1/14; G01R 33/36

(57) ABSTRACT

The invention pertains to a radio frequency receiver system (1) comprising a radio frequency coil circuit (2), a pre-amplifier (3) configured to receive magnetic resonance signals from the coil circuit and configured to output an amplified signal to a digitizer and control system (4), a detuning circuit (5) comprising a switch (6) configured to switch the radio frequency coil circuit between a detuned state and a tuned state based on a detune-command signal received by the detuning unit (5), and a single two-wire connection (7) which is configured to transmit electrical power to the pre-amplifier (3), to transmit the detune-command signal to the detuning circuit (5) and to carry the amplified receive signal. In this way, a radio frequency antenna system with improved characteristics is provided.

### FIELD OF THE INVENTION

The invention relates to the field of magnetic resonance imaging. In particular, the present invention relates to the field of radio frequency antenna systems for a magnetic resonance imaging device. The invention further relates to a radio frequency (RF) antenna or receiver assembly comprising an RF coil loop for pick-up of magnetic resonance signals, a pre-amplifier to amplify the magnetic resonance signals and a detuning circuit for switching the RF coil assembly between a detuned state (“off” state) and a tuned state (“on” state). The detuning circuit preferably includes a FET-based switch to switch the RF antenna assembly between the “on” state and the “off” state.

### BACKGROUND OF THE INVENTION

A part of every magnetic resonance imaging device is the radio frequency antenna system for receiving and converting the magnetic resonance signal. The radio frequency antenna system comprises a radio frequency coil, a matching network, a preamplifier and an analog-to-digital converter. The preamplifier supply voltage and the amplified signal are routed between antenna system and system back end using a first cable connection per antenna element. In magnetic resonance imaging the system integrated body coil generates the excitation magnetic field for the spin system causing a preceding relaxation. The precession of the net magnetization induces a current in the radio frequency coil via electromagnetic induction. The radio frequency coil generally comprises a conducting wire with an inductance and a coil resistance.

Like any radio frequency operated system, the radio frequency antenna system is subject to noise. Thereby, one of the most important requirements is to achieve a minimum noise figure. The lowest noise figure is achieved if the source impedance is matched to the noise impedance of the preamplifier. Especially for magnetic resonance imaging in the low field range (<1 T), the signal-to-noise ratio, inter alia, depends on the patient geometry, the size of the bore and the relative position of the radio frequency coil within the bore. Further sources of noise are modulated power supplies that can lead to further increased noise or instability of preamplifiers, latency and gain instability leading to reduction of image quality.

With the advent of light weight digital RF coils for MRI, coils can be equipped with smart functionality to provide safe clinical workflow.

Magnet resonance (MR) coils for signal reception normally have two operational states: An “on” state, also called tuned state, which represents a low noise reception state for capturing of very weak (down to noise floor) nuclei signals. The other operational state is an “off” state, also called detuned state, which represents a passive state, in which the coils need to withstand strong RF pulses intended to excite nuclei. For switching, typically RF switches based on PIN diodes are used. The detune circuit requires a bias current though the diode of typically 80 mA. The supply of the detune circuit is realized using a second feeding supply cable between an individual antenna element and MR system. This makes the cable tree of the coil less flexible. One option would be to combine the first and second cable, in a 3-conductor structure, with e.g. shared return wire. But this greatly increases the risk of instability of preamplifiers for RF coils due to the strong transient currents on the cables. Furthermore, the control logic is expensive since the bias currents sum up to several Amperes in multi-channel coils in one of the operational phases. Strong losses have to be expected and the design of the feeding wires is challenging as the strong currents may not interfere with the BO or gradient fields.

With the further advent of switches based on FETs (Field Effect Transistors), FET arrays or MEMs, RF currents, e.g. induced by the RF transmit pulse, are effectively blocked in the coil loop without the need of high detune currents. These newer detune circuits are fully voltage controlled, typically between 0 and 3V, and operate almost powerless in the two operational states of the coil.

Due to the complexity of the requirements, currently, two wire connections are needed to control a coil element. One connection is usually used for the RF signal and the DC supply of the preamplifier, whereas a second connection is used to route the detune current. This increases the complexity of trapping and contributes to electrical fields due to dual conductor feeding and trapping. In consequence this may cause signal integrity problems using digital solutions. Furthermore, this normally increases power consumption by additional digital electronics. Another requirement which permanently needs to be fulfilled is the patient's safety by control of the detune function.

WO 2007/138547 A1 describes a RF receiver assembly with a coaxial-based RF coil loop with a reactively coupled detune circuit. The switching is realized by a switching supply voltage for the preamplifier. The preamplifier is directly modulated by the switching supply voltage, which can lead to instability and image artefact issues. Hence remote detection of malfunction via a single two-wire or coaxial cable or connector remains a challenge.

### SUMMARY OF THE INVENTION

It is the object of the invention to provide a radio frequency antenna system with improved characteristics.

According to the invention, this object is addressed by the subject matter of the independent claims. Preferred embodiments of the invention are described in the dependent claims.

The invention relates to a radio frequency receiver system comprising a radio frequency coil circuit, a pre-amplifier configured to receive magnetic resonance signals from the coil circuit and configured to output an amplified signal to a digitizer and control system, the radio frequency receiver system further comprising a detuning circuit comprising a switch configured to switch the radio frequency coil circuit between a detuned state and a tuned state based on a detune-command signal received by the detuning unit, and a single dual mode, e.g. a two-wire connection or a coaxial connection which is configured to transmit electrical power to the pre-amplifier, to transmit the detune-command signal to the detuning circuit and to carry the amplified receive signal.

According to the invention a single dual mode connection e.g. a two-wire or coaxial cable is provided to supply electrical DC power to the pre-amplifier, to control the tune/detune state and to transfer the amplified magnetic resonance (MR) signal to and from the magnetic resonance examination system's (digital) control and reconstructor. The invention achieves to reduce the amount of cabling for data transfer, detuning control and power supply from/to the RF antenna assembly.

The invention concerns a RF receiver system for use in a magnetic resonance examination system. In particular the RF receiver system comprises a RF coil circuit that functions to pick of magnetic flix of magnetic resonance signals. A pre-amplifier is provided for pre-amplifying the picked-up magnetic resonance signals. In order to de/tune the RF circuit a de/tune circuit is provided to switch the impedance of the RF coil circuit with the de/tune circuit between a resonant and a non-resonant mode. In the resonant mode the RF coil circuit is highly sensitive for the magnetic resonance signals that have a carrier frequency in the (Larmor, or MR) frequency range. In the non-resonant mode the RF coil circuit has very low sensitivity for RF transmit signals in the Larmor frequency range that are generated by the RF transmit function of the magnetic resonance examination system for excitation and manipulation (inverting, refocusing etc.) of the excited transverse spins of the subject to be examined (patient to be imaged). In the detuned mode the non-resonant RF coil circuit shield the sensitive pre-amplifier for strong RF transmit field emitted by the magnetic resonance examination system's RF transmitter.

A single dual mode connection is provided between the (i) RF coil circuit with the pre-amplifier and the de/tuning circuit and (ii) the digitizer and control circuit. Hence, the invention achieves to reduce the amount of cabling between the front-end and back-ends to the RF receiver system, in that only a single cable is required in the examination zone of the magnetic resonance examination system where space is usually scarce. While the single dual mode connection functions to carry various signals from and to the RF coil circuit with the detune circuit, the front-end three port network achieves that the electrical power signal is passed to the pre-amplifier and the pre-amplifier is shielded from the detune command signal. Further, the front-end three-port network serves to apply the pre-amplified magnetic resonance signal from the pre-amplifier onto the single dual mode connection. The single dual mode connection further conveys the electrical power signal as well as the detune command signal form the digitizer and control circuit to the RF coil circuit and with the detune circuit. The front-end three-port network serves to shield the pre-amplifier from the detune command signal. The electrical power signal and the detune command signal are conveyed to the pre-amplifier's power input and to control the switch of the detune circuit, respectively.
The back-end three-port network serves to convey the pre-amplified magnetic resonance signal from the single dual mode connection to the receiver function of the digitizer and control system. Further, the back-end three-port networks serve to apply the electrical power single and the detune command signal onto the single dual mode connection towards the RF receiver coil circuit with the de/tuning circuit. In particular, the electrical power signal may be implemented as an RF power signal and the detune command signal may for formed as a (AM, FM or phase) modulation of the RF power signal. The back-end three-port network serves to combine the RF power signal and the detune command signal into a superposition signal applied to the single dual mode connection. The front-end three-port network serves the shield the pre-amplifier from the modulation representing the detune command signal.

The back-end three-port network serves to apply the injected RF signal formed as the DC power signal and superposed modulation that represents the de/tune signal onto the single dual-mode connection. The front-end three-port network serves to divide the modulated DC (power and de/tune modulation) from the single duel-mode connection into a

It has been discovered that a single cable control of the MRI control loop is advantageous using a select over a two-wire or coaxial signal to control the fully voltage controlled detuning circuit. The method provides an effective detuning of the MRI coil loop. The detection of the detuning circuit is realized via a nonlinear device or by impedance switching on a different frequency.

An antenna comprises an electrical element which in general can receive and/or transmit signals.

A digitizer and control system typically comprises a system that transforms or further processes the (raw) data to interpretable data like image data which normally consist of two-dimensional greyscale-images, also known as “slices”, for visualization of contrasts. Hence a digitizer and control basically reconstructs the data that is acquired by the sensor system itself.

A diplexer usually frequency-multiplexes two ports onto one port, but more than two ports may be multiplexed. The diplexer, being a passive device, is normally reciprocal: the device itself doesn't have a notion of input or output. The diplexer comprises typically a different device than a passive combiner or splitter. The ports of a diplexer are frequency selective; the ports of a combiner are not.

MR coils are turned on and off using radio frequency (RF) switches typically based on PIN-diodes. In general, a PIN-diode usually comprises a diode with a wide, undoped intrinsic semiconductor region between a p-type semiconductor and an n-type semiconductor region. The p-type and n-type regions are typically heavily doped in order to use them for ohmic contacts. The wide intrinsic region of a PIN-diode is in contrast to an ordinary p-n diode. The wide intrinsic region makes the PIN diode an inferior rectifier—which is one typical function of a diode—but it makes it applicable for attenuators, fast switches, photodetectors, and high-voltage power electronics applications.

In a preferred embodiment the radio frequency receiver system comprises a front-end diplexer at the side of the single two-wire or coaxial connection directed to the radio frequency coil circuit. Preferably the front-end diplexer is configured to isolate the pre-amplifier from the detune control and monitoring signal flow based on injected radio frequency signals.

In a preferred embodiment a back-end diplexer is located at the side of the single two-wire or coaxial cable directed to the digitizer and control system. Preferably the back-end diplexer is configured to isolate the digitizer and control system from other signals that are not required by the digitizer and control system.

In a preferred embodiment the back-end diplexer is configured to output the amplified magnetic resonance signal and receive an injected radio frequency signal generated by the digitizer and control system. Therefore the back-end diplexer preferably outputs the amplified MR-signal and receives an injected RF signal that is filtered to form the gate signal for the fully voltage-controlled switch (i.e. a FET) to switch the detuning circuit.

In another preferred embodiment the front-end diplexers and the back-end diplexer are configured to isolate control signals, MR-data and electrical power. This further allows the use of only a single (coax) cable as a main connection to a MR-scanner and hence the reduction of cable connections by multiplexing of different frequencies and therefore also the use of different channels.

In a further preferred embodiment the digitizer and control system is configured to generate a RF signal modulated to control the tune/detune actors for the switch of the detuning circuit. A filtering and rectification is usually performed to correct the signals and obtain a signal that has only little or negligible deviations from the originally sent signal, because data transmissions suffer from many effects that unintentionally alter the original signal.

In another preferred embodiment the detuning circuit comprises a nonlinear device and/or an impedance switching on a different frequency. A nonlinear device usually comprises an electric component that has a characteristic response curve that is different from a linear curve. Thus a nonlinear component basically has a response or output signal that is not simply proportional to the input signal. Impedance switching preferably comprises the change of the complex resistance (impedance). By this a tuning or detuning effect can be achieved.

In a further preferred embodiment, the switch of the detuning circuit comprises a field effect transistor. The field-effect transistor (FET) is a type of transistor that uses an electric field to control and regulate the flow of current in a semiconductor. FETs (JFETs or MOSFETs) are devices with three terminals: source, gate, and drain. FETs control the flow of current by the application of a voltage to the gate, which in turn alters the conductivity between the drain and source. In a preferred embodiment more than one FET is used which allows to achieve a better switching performance. Such arrays of FETs are often available in a single package in combination with control and/or potentially monitoring logic. Single pole single throw (SPST) and single pole double throw (SPDT) are typical examples for such integrated circuits (ICs). The core switching actor may not only be a semiconductor, but also be based on other fully voltage-controlled technology such as MEMS (Micro-Electro-Mechanical Systems). The SPST, SPDT and MEMS based devices are complex integrated circuits and can directly be applied as switching actor.

In a preferred embodiment the detuning circuit is configured to be controlled by external detune commands. This allows an external control and hence also a remote control which is of high value in most applications. Preferably, external detune commands originate from a system host.

In a preferred embodiment the detuning circuit comprises a voltage-step-up circuit for matching the demands of signal transmission and tuning actors. This way for instance the injected RF power can be reduced. In general, a voltage-step-up circuit is a circuit which increases the voltage and it can function as an adjustable voltage regulator. The voltage-step-up circuit can comprise a Villard-type circuit.

According to another embodiment of the invention the switch of the detuning circuit is monitored by a detection circuit. Preferably the DC bias and/or select and/or control signals and/or output of the switch are monitored by the MRI system. The respective parameter can be monitored in real time. In case of a malfunction, the MRI scan can be stopped.

In a preferred embodiment the digitizer and control system comprises a digital synthesizer. A digital synthesizer is preferably a synthesizer that uses digital signal processing (DSP) techniques to combine different signals and/or frequencies.

The invention also relates to a magnetic resonance imaging system comprising a processor, a memory for storing machine executable instructions for execution by the processor and pulse sequence commands, and the already characterized radio frequency receiver system.

The invention also relates to a method for controlling a radio frequency receiver system, comprising the following steps: detecting a radio frequency signal with a radio frequency coil circuit, receiving the magnetic resonance signals from the radio frequency coil circuit with a pre-amplifier which sends an amplified signal to a digitizer and control system, switching the radio frequency coil circuit between an detuned state and a tuned state with a detuning circuit, wherein a single two-wire or coaxial connection is used for transmitting the electrical power to the pre-amplifier and for transmitting the detune command signal to the detuning circuit.

The invention further relates to a method comprising the steps of monitoring the detune circuit by (a) measuring the RF current in a parallel resonant detuning circuit, mixing the signal of the probe with a pilot signal and transmitting back the mixed signal output to an analogue to digital converter of the MR receive channel or to a separate dedicated input with less dynamic range or by (b) feeding a detector switch with the signal of the probe and detecting the change of the frequency selective impedance transition during transmission at the output of the feeding cable or by (c) a detector switch only grounding the DC voltage when a malfunction is detected.

The detector switch is typically located between the probe or a detector module and the two-wire connection. Preferably the detector switch comprises a FET or semiconductor-based switch.

### BRIEF DESCRIPTION OF THE DRAWINGS

These and other aspects of the invention will be apparent from and elucidated with reference to the embodiments described hereinafter. Such an embodiment does not necessarily represent the full scope of the invention, however, and reference is made therefore to the claims and herein for interpreting the scope of the invention.

In the drawings

FIG. 1 schematically depicts a radio frequency receiver system according to a preferred embodiment of the invention with a single RF loop, a single micro coaxial cable or connector and a remote RF injection for fast coil detuning and

FIG. 2 schematically depicts a second radio frequency antenna system according to a preferred embodiment of the invention with an individual coil element with malfunction detection using a single coaxial connector.

### DETAILED DESCRIPTION OF EMBODIMENTS

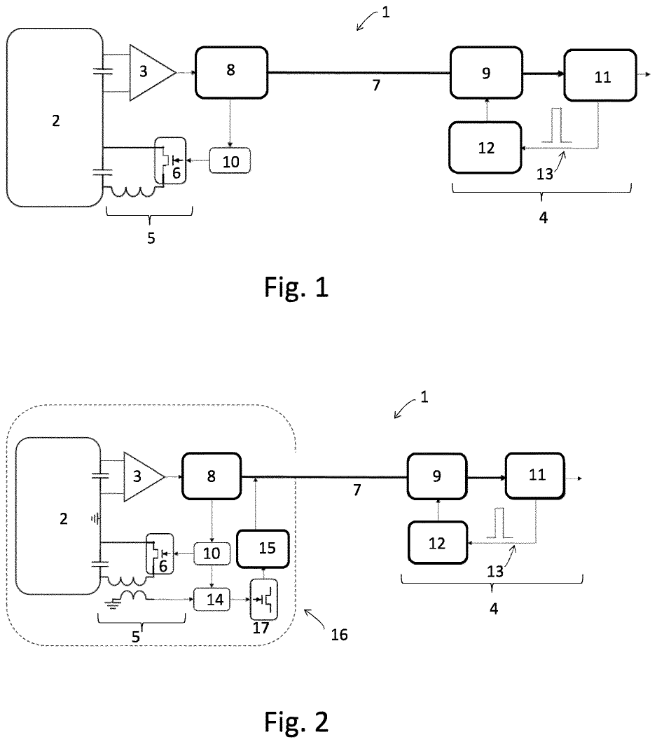

FIG. 1 schematically depicts a radio frequency receiver system 1 according to a preferred embodiment of the invention with a single radio frequency coil 2, a single micro coaxial cable or connector 7 and a remote radio frequency (RF) injection for fast coil detuning. As shown in FIG. 1 a single coaxial connection 7 is used for the MRI pre-amplifier 3 and the control of the detune circuit 5. While the pre-amplifier 3 is supplied with a constant supply voltage (typically 9V), the detune circuit 5 is controlled via an injected RF signal generated by a transmitter. The RF control signal is injected via a front-end diplexer 8 into the coaxial connector and separated by a second diplexer, also named back-end diplexer 9, in the radio frequency coil circuit 2. The switched RF signal is filtered and rectified to generate a DC gate voltage for the switch 6. The single radio frequency coil typically consists of a loop using a wire as depicted in FIG. 1. The conductor loop can also be built up using a two-wire connection like a coaxial cable or combinations of distributed capacitor with discrete capacitors. The capacitor in the detune circuit 5 can be a local capacitor or a distributed capacitor, transmission line or any kind of device (coil, transmission line etc.) The switching device 6 generates—in general by the on off switching in combination with a impedance—a on and off state of the coil. A voltage-step-up circuit 10, in particular a Villard cascade voltage multiplier, can be further applied to reduce the injected RF power, especially for matching the demands of signal transmission and tuning actors. For example, MEMS switches require high control voltages in the range of 100V at virtually zero current. Such a high voltage is hard to generate or transmit or diplexed. The pre-amplifier 3 is isolated via the front-end diplexer 8 from the injected control signal. A pulsed RF power of 50 mW can generate 1.58V rms, which can be further increased using a passive voltage doubler.

The transmitter for the RF pilot or select signal is realized as a digital synthesizer. The frequency, amplitude and phase can be controlled by the digital receiver 11. The digital receiver 11 typically comprises a fully integrated circuit, which incorporates a digital synthesizer, or the digital synthesizer is located remotely and routed to the digital receiver 11. A local digital synthesizer can be located at the digitizer and control system 4 and be controlled via the digital receiver 11 or by a further digital control signal optically or galvanically. A further option is for instance to use a fixed analog signal and/or a quartz oscillator. The digitizer and control system 4 can be used for managing the tune/detune state timing and malfunctions reported by the coil element (16). Further it can be used for digitizing the RX signal and generating the supply voltage for the preamplifier. The digitizer and control system's 4 output to the right (see arrow in FIG. 2) can be fed to a reconstructor (not shown). Simultaneously to/from further not shown units it can receive control commands and a synchronization signal. The signal generator 12 modulates its output according to blank control 13. The diplexer 9 performs a mixing of the signals to one channel. To transmit all signals over a single two-wire connection a DC signal controlling is enhanced and replaced by the switching actors of the coil from a two stage DC signal (e.g. −5/+5V or 0 and 3V) to a signal with an AC signal as a carrier of the control demand.

The frequency of the RF detune signal TX 12 is selected so that the three basic signals (DC preamp supply, RF detune signal (TX) and MRI (RX) signal) can easily be separated.

In a very simple set-up, the RF detune signal (TX) signal is a simple (pulsed) DC voltage overlayed to the DC preamp supply voltage. The pulsed signal can be provided with the help of the digital receiver 11 and a blank control signal 13. For example, should the coil be tuned or detuned, depending on the implementation of the RF detune signal 12, the signal high corresponds to detuned and low (blank) corresponds to tuned or vice versa. In a simple implementation the RF detune signal 12 is a crystal oscillator with an amplifier for the oscillator output, then blank means not to amplify the output in case it is not needed.

The modular design can be applied at different MRI field strength or nuclei. Further the amplitude of the switching carrier is adapted to the correct and safe control of the detuning circuit (5). The pilot signal can also be modulated to optimize the switching behaviour of the rectifier circuit and to reduce latency.

In the following three possibilities are described for monitoring the detune circuit 5. FIG. 2 shows an individual coil element with malfunction detection using single coaxial connector 7. The signal of the probe is feeding a FET transistor, which shortens the coaxial connector 7 via a filter at a reference plane (location at output at pre-amplifier 3). The change of the frequency selective impedance transition during transmit can be detected at the output of the feeding cable.

The second possibility for monitoring the detune circuit 5—especially in the framework of SAR safety monitoring—can be realized by measuring the current in the parallel resonant detuning circuit. The measurement can be performed by an inductive/capacitive coupling probe. The signal of the probe is mixed (non-linear device, diode, mixer) with the select/pilot signal and the mixed signal output is transmitted back to an ADC of the MR receive channel 11 or to a separate dedicated input with less dynamic range. For this option of monitoring the detune circuit, the FET and a notch filter 15 are replaced by a mixer.

The third possibility for monitoring the detune circuit 5 is that the switch 6 or field effect transistor (FET) only grounds the applied DC voltage when there is a malfunction. The DC voltage can easily be detected via a single coaxial cable or connector.

While the invention has been illustrated and described in detail in the drawings and foregoing description, such illustration and description are to be considered illustrative or exemplary and not restrictive; the invention is not limited to the disclosed embodiments. Other variations to the disclosed embodiments can be understood and effected by those skilled in the art in practicing the claimed invention, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to advantage. Any reference signs in the claims should not be construed as limiting the scope. Further, for the sake of clearness, not all elements in the drawings may have been supplied with reference signs.

### REFERENCE SYMBOL LIST

Radio frequency receiver system 1
Radio frequency coil circuit 2
Pre-amplifier 3
Digitizer and control system 4
Detuning circuit 5
Switch 6
Two-wire connection 7
Diplexer 8, 9
Voltage-step-up circuit 10
Digital receiver/MR receive channel 11
RF detune signal (Tx) 12
Blank control 13
Detector 14
Notch filter 15
Individual coil element 16
Detector switch 17

1. A radio frequency receiver system comprising:
a radio frequency coil circuit,
a digitizer and control system including a digital receiver
a single dual mode connection extending between a front-end three-port network at the side of the single dual mode connection directed to the radio frequency coil circuit and a back-end three-port network at the side of the single dual mode cable directed to the digitizer and control system;
a pre-amplifier configured to receive magnetic resonance signals from the radio frequency coil circuit and coupled between the radio frequency coil circuit and the front-end three-port network
a detuning circuit comprising a switch configured to switch the radio frequency coil circuit between a detuned state and a tuned state based on a detune-command signal from digital receiver received by the detuning unit, wherein
the front-end three-port network is configured to receive an amplified magnetic resonance signal form the pre-amplifier, apply the amplified magnetic resonance signal to the single dual mode connection, receive the detune command signal superposed on a power signal from the single dual mode connection and forward the detune command signal towards the detuning circuit,
the back-end three-port network configured to receive the pre-amplified magnetic resonance signal from the single dual mode connection and apply the amplified magnetic resonance signal to the digital receiver, receive the detune control signal from the digitizer and control system and apply the detune command signal superposed on the power signal to the single dual mode connection, so that
the single dual mode connection is configured to transmit electrical power carried by the power signal to the pre-amplifier, to transmit the detune-command signal to the detuning circuit and to carry the amplified receive signal and
the front-end three-port network is further configured to isolate the pre-amplifier from the detune control signal,
the back-end three-port network is further configured to output the amplified magnetic resonance signal towards the digital receiver and to forward the detune control signal towards the front-end in form of an injected radio frequency signal generated by the digitizer and control system.

2. The radio frequency receiver system according to claim 1, wherein the front-end three-port network and the back-end three-port network as configured as diplexers.

3. The radio frequency receiver system of claim 1, wherein Radio frequency receiver system according to claim 2, wherein the front-end three-port network and the back-end three-port network as configured bias-T circuits.

4. The radio frequency receiver system according to claim 1, wherein the front-end three-port network and the back-end three-port network are configured to isolate control signals, magnetic resonance data, and electrical power.

5. The radio frequency receiver system according to claim 1, wherein the digitizer and control system is configured to generate a RF signal modulated to control the tune/detune actors for the switch of the detuning circuit.

6. The radio frequency receiver system according to claim 1, wherein the detuning circuit comprises a nonlinear device and/or an impedance switching on a different frequency.

7. The radio frequency receiver system according to claim 1, wherein the switch of the detuning circuit comprises at least one field effect transistor.

8. The radio frequency receiver system according to claim 1, wherein the detuning circuit is configured to be controlled by external detune commands.

9. The radio frequency receiver system according to claim 1, wherein the detuning circuit comprises a voltage-step-up circuit for matching the demands of signal transmission and tuning actors.

10. The radio frequency receiver system according to claim 1, wherein the digitizer and control system comprises a digital synthesizer.

11. A magnetic resonance imaging system comprising
a processor,
a memory configured to store machine executable instructions for execution by the processor and pulse sequence commands, and
a radio frequency receiver system according to claim 1.

12. A method for controlling a radio frequency receiver system, the method comprising:
detecting a radio frequency signal with a radio frequency coil circuit,
receiving the magnetic resonance signals from the radio frequency coil circuit with a pre-amplifier which sends an amplified signal to a digitizer and control system,
switching the radio frequency coil circuit between a detuned state and a tuned state with a detuning circuit, wherein
a single dual mode connection extending between a front-end three-port network at the side of the single dual mode connection directed to the radio frequency coil circuit and a back-end three-port network at the side of the single dual mode cable directed to the digitizer and control system;
transmits the electrical power to the pre-amplifier and transmits the detune command signal to the detuning circuit.

13. The method according to claim 12, further comprising monitoring the detune circuit by (a) measuring the RF current in a parallel resonant detuning circuit,
mixing the signal of the probe with a pilot signal and
transmitting back the mixed signal output to an analog to digital converter of a magnetic resonance receive channel or to a separate dedicated input with less dynamic range.
or by
(b) feeding a detector switch with the signal of the probe and
detecting the change of the frequency selective impedance transition during transmission at the output of the feeding cable
or by
(c) a detector switch only grounding the DC voltage when a malfunction is detected.
